(19) United States
(12) Patent Application Publication
(10) Pub. No.: US 2007/0146974 A1
(43) Pub. Date: Jun. 28, 2007

(54) Electrical circuit pattern design by injection mold

(76) Inventors: Cleopatra Cabuz, Edina, MN (US); Eugen I. Cabuz, Edina, MN (US); Tzu-Yu Wang, Maple Grove, MN (US)

Correspondence Address: Kris T. Fredrick, Esq.;Patent Services, Honeywell International Inc., 101 Columbia Road, Morristown, NJ, 07962, US

(21) Appl. No.: 11/318,033

(22) Filed: Dec. 23, 2005

(51) Int. Cl. H05K 5/00

(52) U.S. Cl. 361/679

(57) ABSTRACT

A method of forming an electronic part having a circuit pattern, by forming a cavity mold having trench lines in the cavity mold with a first area perpendicular to an axis and a second area having a negative slope with respect to the axis. The part is molded and removed, and a conductive material is deposited to form conductive and nonconductive areas thereon. The preferred deposit step is by blanket metallization which coats all surfaces except the sides of the trench lines and the second area of the part. The method may include the additional step of molding vertical flash portions on the part instead of or in addition to the trench lines that are removed after the conductive material is deposited thereon to form the circuit pattern.

### FIELD OF THE INVENTION

The present invention relates to the formation of electrical circuit lines on electronic devices. More particularly, the invention relates to the use of a novel mold design to create the desired circuit design in the mold from which the electrical device or part is made.

### BACKGROUND OF THE INVENTION

A wide variety of electronic devices are currently being manufactured and many of them require electrical circuit lines to be defined on a plastic part. Examples of these devices are valves, pumps and sensors made from plastic, such as the family of meso devices such as electrostatic actuators, pumps arrays and the like.

In these devices, the parts are molded and then electrical circuit lines are pattern coated using metallization, either through a patterned additive process or a blanket addition and patterned subtraction process. These methods are very common in the manufacture of many electronic devices.

It would be of advantage in the art if a simple process could be developed that would eliminate the need for a second step in forming circuit lines in such electronic devices.

Another advantage would be if a method could be developed that would allow for a simple metallization step to be performed after formation of a patterned substrate for the electronic device.

Other advantages will appear hereinafter.

### SUMMARY OF THE INVENTION

It has now been discovered that the above and other advantages of the present invention may be obtained in the following manner. Specifically, the present invention provides for inclusion of a circuit design in an injection mold prior to molding the electronic part. This permits the elimination of costly use of pattern coated metallization through patterned additive or subtraction processes.

The method of forming the electronic part having a circuit pattern is done in a conventional manner except that the cavity mold includes trench lines having a first area perpendicular to an axis and a second area having a negative slope with respect to the axis. After the part is molded and removed, a conductive material is deposited to form conductive and nonconductive areas thereon which make up the desired circuit pattern. The electronic part is any molded device made from plastic or other nonconductive materials such as, by way of example and not as a limitation, mesovalves, dual chamber mesovalves, meso arrays, printed circuit boards, printed circuit boards with conductive access to a back side and the like.

The preferred deposit step is by blanket metallization which coats all surfaces except the sides of the trench lines and the second area of the part.

The method may include the additional step of molding vertical flash portions on the part instead of or in addition to the trench lines that are removed after the conductive material is deposited thereon to form the circuit pattern. Blanket metallization is a preferred method of applying the conductive material and a beam process is most preferred to coat all surfaces except the sides of the trench lines and the second area of the part formed by the mold.

Another embodiment of the present invention includes filling the trench lines with a nonconductive material in the part after removing the part from the mold and prior to depositing the conductive material thereon. Preferably the nonconductive material does not adhere to the part.

The present invention includes an alternative step of molding vertical flash portions with respect to said axis on said part instead of or in addition to the trench lines and removing the vertical flash portions after the conductive material is deposited thereon to form the circuit pattern

### BRIEF DESCRIPTION OF THE DRAWINGS

For a more complete understanding of the invention, reference is hereby made to the drawings, in which:

FIG. 1 is a plan view of one embodiment of the present invention;

FIG. 2 is a side elevational view taken along line 2-2 in FIG. 1;

FIG. 3 is a side elevational view taken along line 3-3 in FIG. 1;

FIG. 4 is a plan view of another device to which the present invention has been applied;

FIG. 5 is a plan view of yet another device to which the present invention has been applied;

FIG. 6 is a plan view of still another device to which the present invention has been applied;

FIG. 7 is a plan view of an alternative view of the device of FIG. 6; and

FIGS. 8a and 8B are side elevational views of an alternative embodiment of the present invention.

### DETAILED DESCRIPTION OF THE PREFERRED EMBODIMENT

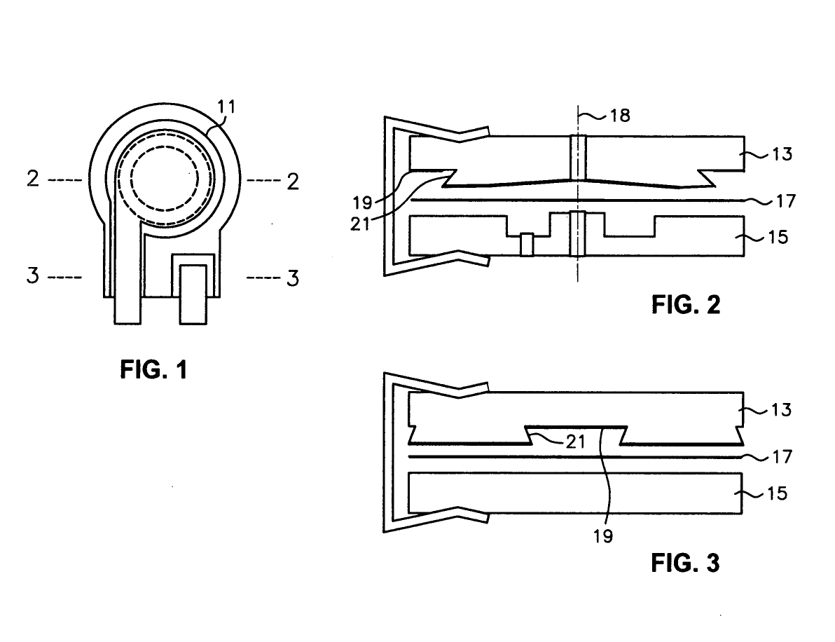

The present invention provides for a method of forming an electrical circuit on an electronic part in a manner that is faster, more economical and more precise. FIG. 1 illustrates the top of a mesovalve top chamber 11 with leads that are shown in FIGS. 2 and 3 as metalized portions 19 on top part 13 and bottom part 15 of the chamber 11 so that electrical energy applied to selected metalized portions 19 causes diaphragm 17 to move to the upper part 13 or lower part 15 in a conventional manner.

The part has been formed by molding in an injection molding process in which the areas 21 have a negative slope with respect to axis 18. By negative slope is meant having a slope or shape that moves toward the axis 18, as seen in FIGS. 2 and 3, and thus areas 21 are shielded from any metallization that is parallel to axis 18. The method of this invention comprises the steps of forming trace lines or trenches in the mold so that the part produced by the mold will have that negative slope. The trench lines have a first area perpendicular to axis 18 and a second area having a negative slope with respect to axis 18. After molding the part and removing it, a conductive material 19 is deposited by blanket metallization, i.e., by a beam process that evaporates, or IB sputters, or sprays in a direction parallel to axis 18 so that all portions 19 have a conductive material deposited thereon and none of the negative slope areas 21 have any conductive material.

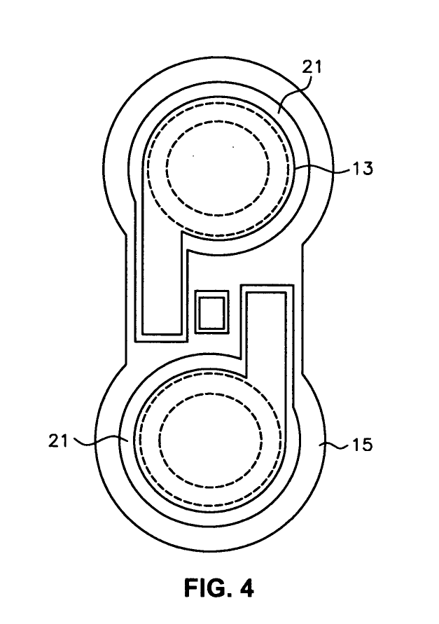

FIG. 4 illustrates a mesovalve dual top chamber electronic device with a top chamber set 13 and lower part 15. Areas 21 were formed with a mold having a negative slope, as in FIGS. 2 and 3, and thus are not conductive.

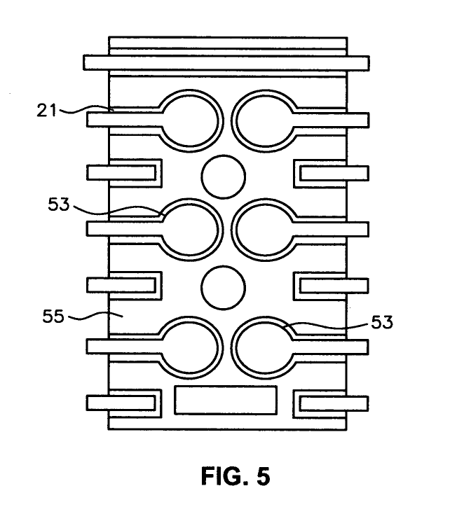

In FIG. 5, a meso array is shown with upper surface 53 and lower surface 55. Nonconductive areas 21, formed by use of a mold with a negative slope with respect to the axis perpendicular to the array and thus separate the plurality of individual meso valves that form the array.

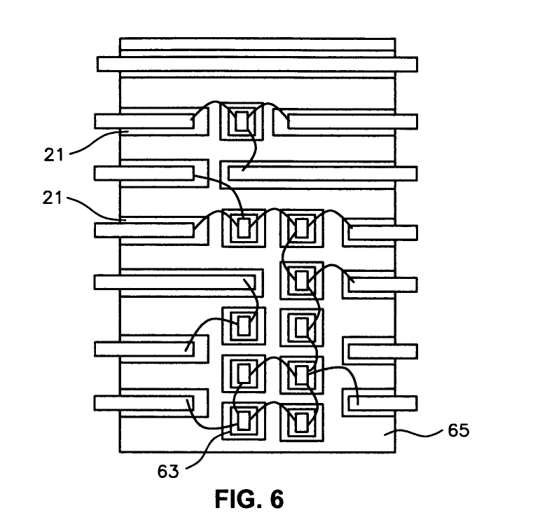

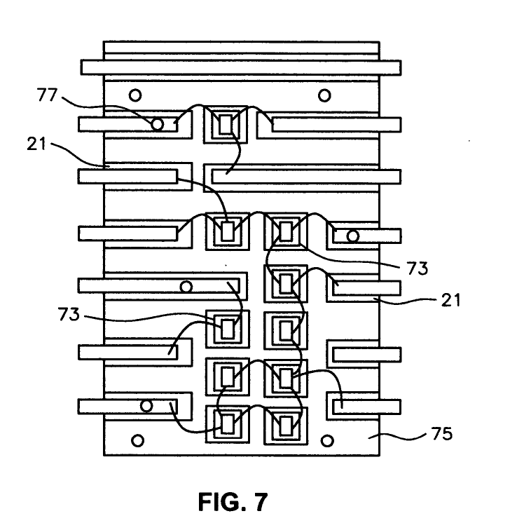

FIG. 6 illustrates a printed circuit board where the lower surface 65 supports a plurality of devices 63, such as transistors, resistors, capacitors and the like. Nonconductive areas 21 are formed from a mold with a negative slope as in the other illustrations. FIG. 7 is similar to FIG. 6, with a lower surface 75 and the various devices 73, and has conductive vias 77 to the back side of the printed circuit board.

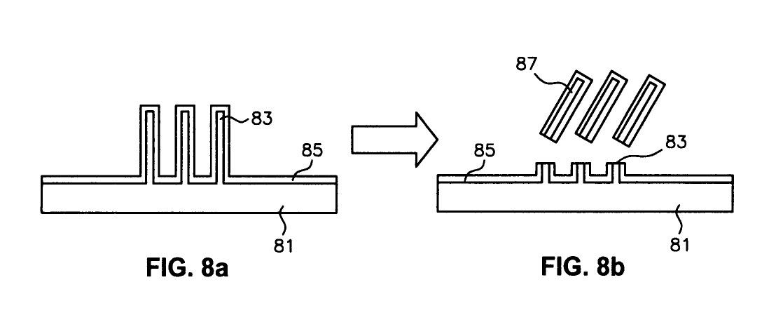

FIG. 8 represents an additional embodiment of the present invention. In FIG. 8, the mold has been designed to form a substrate 81 that extends up vertically from the plane of the substrate 81 with a flash 83. Blanket metallization 85 covers the entire device, after which the vertical flashes 87 are broken or cut to expose the flash 83 and present a circuit pattern without lithographic patterning.

While particular embodiments of the present invention have been illustrated and described, it is not intended to limit the invention, except as defined by the following claims.

1. A method of forming an electronic part having a circuit pattern, comprising the steps of:
forming a cavity mold for said part;
forming trench lines in said cavity mold, said trench lines having a first area perpendicular to an axis and a second area having a negative slope with respect to said axis;
molding said part and removing said part from said mold; and
depositing a conductive material in a direction parallel to said axis, whereby both conductive and nonconductive areas are formed on said part.

2. The method of claim 1, wherein said electronic part is selected from the group consisting of mesovalves, dual chamber mesovalves, meso arrays, printed circuit boards, and printed circuit boards with conductive access to a back side.

3. The method of claim 1, wherein said conductive material is deposited by blanket metallization.

4. The method of claim 3, wherein said blanket metallization by a beam process to coat all surfaces except the sides of the trench lines and the second area of said part formed by said mold.

5. The method of claim 1, which further includes the step of filling said trench lines with a nonconductive material in said part after removing said part from said mold and prior to depositing said conductive material thereon.

6. The method of claim 5, wherein said nonconductive material does not adhere to said trench lines in said part.

7. The electronic part having a circuit pattern formed by the method of claim 1.

8. The electronic part having a circuit pattern formed by the method of claim 4.

9. The electronic part having a circuit pattern formed by the method of claim 5.

10. The method of claim 1, which further includes the step of molding vertical flash portions with respect to said axis on said part instead of said trench lines and removing said vertical flash portions after said conductive material is deposited thereon to form said circuit pattern.

11. A method of forming an electronic part having a circuit pattern, comprising the steps of:
forming a cavity mold means for molding said part;
forming trench line means for forming a circuit pattern in said cavity mold means, said trench line means having a first area perpendicular to an axis and a second area having a negative slope with respect to said axis;
molding said part and removing said part from said mold; and
depositing a conductive material in a direction parallel to said axis, whereby both conductive and nonconductive areas are formed on said part.

12. The method of claim 11, wherein said electronic part is selected from the group consisting of mesovalves, dual chamber mesovalves, meso arrays, printed circuit boards, and printed circuit boards with conductive access to a back side.

13. The method of claim 11, wherein said conductive material is deposited by blanket metallization.

14. The method of claim 13, wherein said blanket metallization by a beam process to coat all surfaces except the sides of the trench lines and the second area of said part formed by said mold.

15. The method of claim 11, which further includes the step of filling said trench lines with a nonconductive material in said part after removing said part from said mold and prior to depositing said conductive material thereon.

16. The method of claim 15, wherein said nonconductive material does not adhere to said trench lines in said part.

17. The electronic part having a circuit pattern formed by the method of claim 11.

18. The electronic part having a circuit pattern formed by the method of claim 14.

19. The electronic part having a circuit pattern formed by the method of claim 15.

20. The method of claim 11, which further includes the step of molding vertical flash portions with respect to said axis on said part instead of said trench lines and removing said vertical flash portions after said conductive material is deposited thereon to form said circuit pattern.
